(19) United States
(12) Patent Application Publication
(10) Pub. No.: US 2009/0298271 A1
(43) Pub. Date: Dec. 3, 2009

(54) METHOD FOR MANUFACTURING A SEMICONDUCTOR DEVICE

(75) Inventors: Seung Bum Kim, Gyeonggi-do (KR); Jae Min Lee, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/346,409

(22) Filed: Dec. 30, 2008

(30) Foreign Application Priority Data
May 27, 2008 (KR) 10-2008-0049294

(51) Int. Cl. H01L 21/4763

(52) U.S. Cl. 438/586; 257/E21.496

(57) ABSTRACT

A method for manufacturing a semiconductor device prevents failure of self-aligned contacts to improve the yield of the semiconductor device. A height of a device isolating film is larger than a height of an active region. A recess region of the device isolating film is planarized by a wet etching process to remove a hard mask layer when a recess gate is etched. A contact plug is then formed in the recess region between adjacent recess gates.

### CROSS-REFERENCE TO RELATED APPLICATION

The priority benefit of Korean patent application number 10-2008-0049294, filed on May 27, 2008, is hereby claimed and the disclosure thereof is incorporated herein by reference in its entirety.

### BACKGROUND OF THE INVENTION

The present invention generally relates to a method for manufacturing a semiconductor device, and more specifically, to a method for manufacturing a semiconductor device that prevents failure of self-aligned contacts.

A threshold voltage (Vt) is the most important parameter in the manufacture of a transistor. The threshold voltage is dependent upon a thickness of a gate oxide film, a channel doping concentration, and a gate material. The threshold voltage causes several phenomena to deviate from theoretical values as the size of the device becomes smaller.

One type of phenomena is a short channel effect generated when a gate channel length is reduced.

Due to the high integration of semiconductor devices, a device that can be operated at a lower operating voltage ranging from 1 to 2V with an improved speed is required. The threshold voltage also requires a lower voltage.

However, it is difficult to control a device due to the short channel effect when the threshold voltage is decreased. The short channel effect causes a Drain Induced Built-in Leakage (DIBL) by hot carriers. Although various attempts have been made to reduce the short channel effect, a satisfactory solution has not been reached due to the high integration of the semiconductor device.

For example, the short channel effect has not been addressed by regulation of the doping concentration.

Recent solutions include a method for forming an ion-implant channel and a Super Steep Retrograde Channel (SSR) through vertically abrupt channel doping, a laterally abrupt channel doping method, and a method for forming a channel having a halo structure through a large angle tilt implant.

In order to overcome limits such as the short channel effect, a channel length is increased using a recess gate.

FIGS. 1a to 1i are cross-sectional views illustrating a conventional method for manufacturing a semiconductor device.

Referring to FIG. 1a, a device isolating film 120 that defines an active region 110 is formed in a semiconductor substrate 100. A hard mask layer 130 is formed over the resulting structure.

Referring to FIG. 1b, after a photoresist film is formed over the hard mask layer 130, a photoresist pattern 135 is formed by an exposing and developing process using a recess mask.

Referring to FIG. 1c, the hard mask layer 130, the active region 110 and the device isolating film 120 are etched using the photoresist pattern 135 as a mask to form a recess 140. The depth of the recess 140 is determined by an etching selectivity difference between the active region 110 and the device isolating film 120.

Referring to FIG. 1d, after the photoresist pattern 135 of FIG. 1b is removed, the residual hard mask layer 130 is removed by an etching process. The recess 140 of the device isolating film 120 is further etched by a wet etching process.

Referring to FIG. 1e, a gate oxide film 150, a polysilicon layer 160, a conductive layer 170 and a hard mask nitride film 180 are formed over the resulting structure including the recess 140. After the photoresist film is formed over the hard mask nitride film 180, a photoresist pattern 185 is formed by an exposing and developing process using a recess gate mask.

Referring to FIG. 1f, the hard mask nitride film 180, the conductive layer 170, the polysilicon layer 160 and the gate oxide film 150 are etched using the photoresist pattern 185 as a mask to form a recess gate 190.

FIGS. 1g to 1i show a magnified view of a region ‘A’ of FIG. 1f.

FIG. 1g shows a region where the device isolating film 120 is etched to form the recess gate 190. A nitride film 200 is formed over the resulting structure including the recess gate 190. The nitride film 200 forms a gate spacer on sidewalls of the recess gate 190.

Referring to FIG. 1h, an insulating film 210 is formed over the resulting structure to fill spaces between adjacent recess gates 190. The insulating film 210 is etched to form a landing plug contact hole (not shown).

Referring to FIG. 1i, a polysilicon layer (not shown) is filled in the landing plug contact hole to form a contact plug 220.

FIG. 2 is a photograph diagram illustrating a problem of the conventional method for manufacturing a semiconductor device.

Referring to FIG. 2, a self-aligned contact (SAC) failure occurs in the gate polysilicon layer and the polysilicon layer for forming a contact plug. A region ‘X’ of FIG. 2 shows a region having the SAC failure.

As mentioned above, in the conventional method for manufacturing a semiconductor device, the SAC failure forms a short circuit with a gate when a contact plug is formed in the memory device. The failure frequently occurs when a recess gate for increasing a channel length is formed due to the high integration of the semiconductor device.

### SUMMARY OF THE INVENTION

Various embodiments of the present invention are directed at a method for manufacturing a semiconductor device. The method prevents failure of self-aligned contacts to improve the yield of the semiconductor device. A height of a device isolating film is larger than a height of an active region. A recess region of the device isolating film is planarized by a wet etching process to remove a hard mask layer when a recess gate is etched. A contact plug is then formed in the recess region between adjacent recess gates.

According to an embodiment of the present invention, a method for manufacturing a semiconductor device comprises: forming a device isolating film that defines an active region over a semiconductor substrate; forming a hard mask layer over the device isolating film and the active region; etching the hard mask layer and the device isolating film to form a recess; removing the hard mask layer and etching the device isolating film to planarize the recess by a wet etching process; and forming a recess gate over the recess.

The device isolating film is higher than the active region.

The device isolating film has a difference in height with the active region ranging from 300 to 600 Å.

The hard mask layer is removed and the device isolating film is etched by an isotropic etching process.

The hard mask layer includes one selected from Tetra Ethyl Ortho Silicate (TEOS), Thermal Oxide and High Density Plasma (HDP).

After the recess is formed, the hard mask layer has a thickness ranging from 150 to 250 Å.

The forming the recess gate includes: forming a gate oxide film, a polysilicon layer, a conductive layer and a hard mask nitride film over the device isolating film including the recess; and etching the hard mask nitride film, the conductive layer, the polysilicon layer and the gate oxide film.

The method may further include forming a spacer on sidewalls of the recess gate.

The spacer includes a nitride film.

The method may further include: forming an insulating film over the the recess gate and the device isolating film; etching the insulating film to form a landing plug contact hole; and filling a conductive material in the landing plug contact hole to form a contact plug.

According to another embodiment of the present invention, a method for manufacturing a semiconductor device comprises: forming a device isolating film that defines an active region over a semiconductor substrate; forming a hard mask layer over the device isolating film and the active region; etching the hard mask layer and the device isolating film to form a plurality of recesses; etching the hard mask layer and the device isolating film to remove the hard mask layer and to planarize the device isolating film; forming a recess gate over each of the plurality of recesses; etching the device isolating film between each pair of adjacent recess gates, wherein the device isolating film between each pair of adjacent recess gates is etched to have a planar surface; and forming a contact plug over the device isolating film between each pair of adjacent recess gates.

### BRIEF DESCRIPTION OF THE DRAWINGS

FIGS. 1a to 1i are cross-sectional views illustrating a conventional method for manufacturing a semiconductor device.

FIG. 2 is a photograph diagram illustrating a problem of the conventional method for manufacturing a semiconductor device.

FIGS. 3a to 3e are cross-sectional views illustrating a method for manufacturing a semiconductor device according to an embodiment of the present invention.

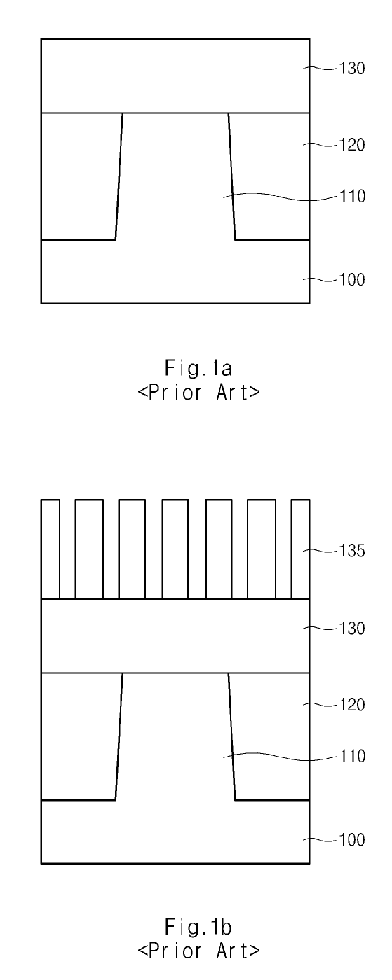

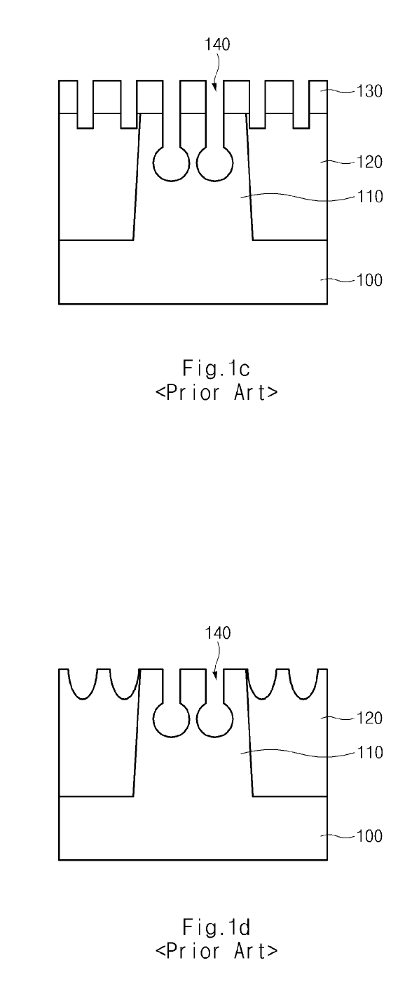

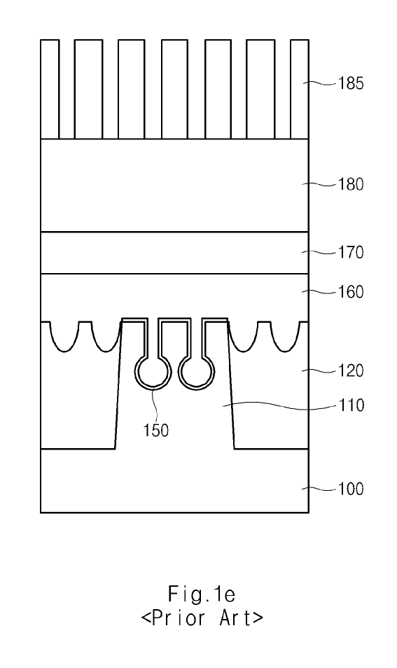

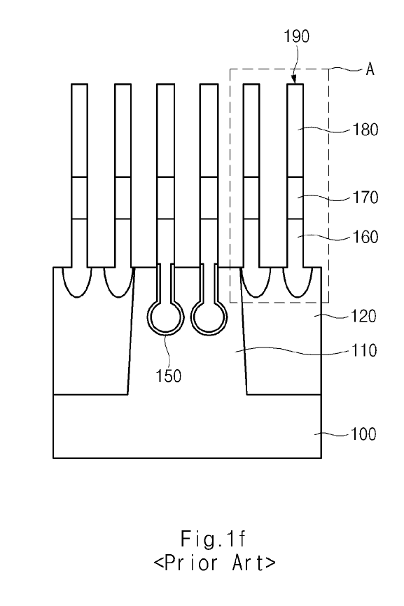

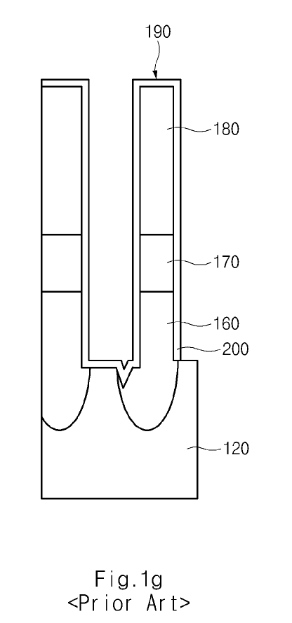

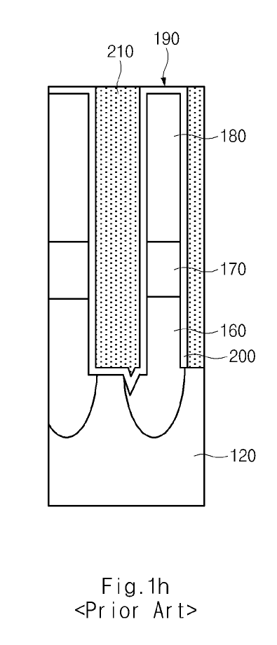

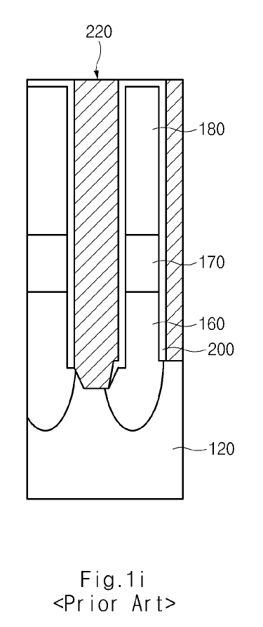

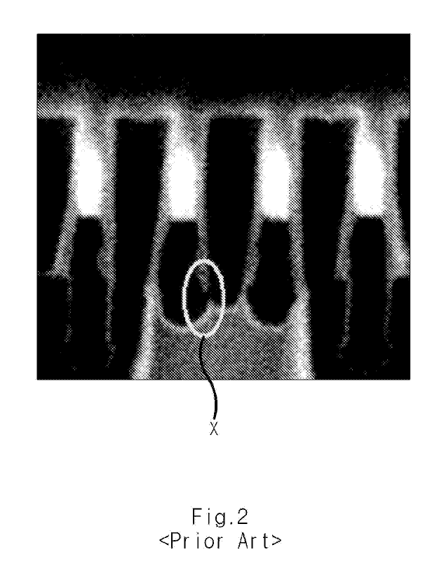

### DETAILED DESCRIPTION OF SPECIFIC EMBODIMENT

The present invention will be described in detail with reference to the drawings. In the drawings, the thickness of layers and regions is exaggerated to facilitate explanation, and a layer can be directly formed over a different layer, a substrate or a third layer can be formed between the different layer and the substrate. The same reference numbers represent the same components.

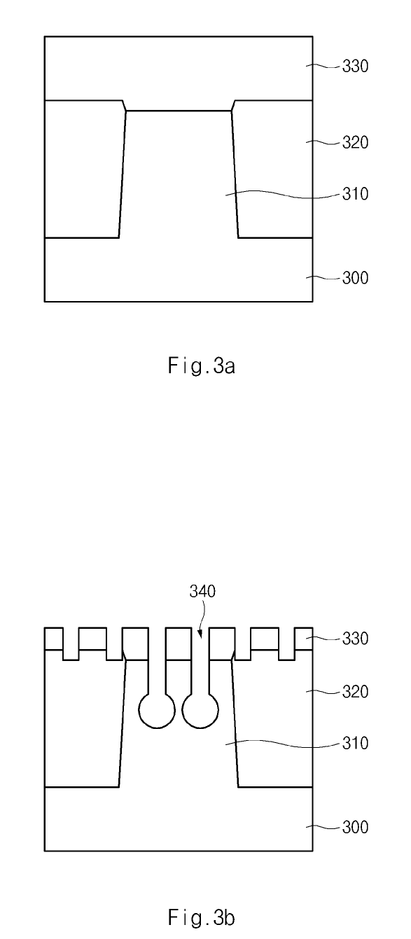

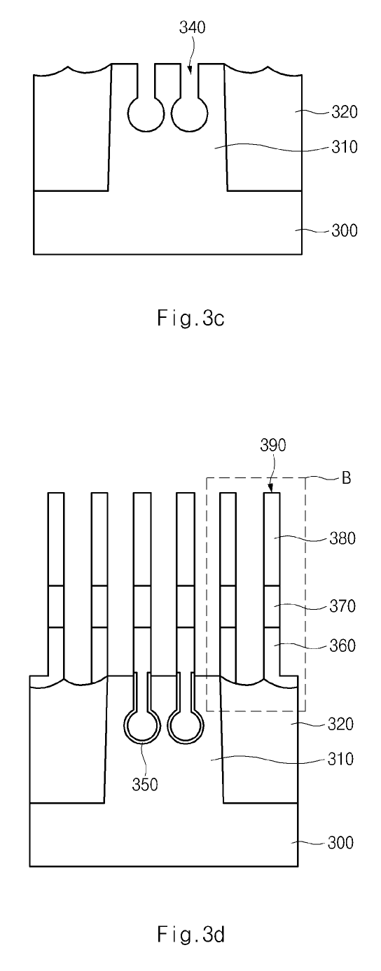

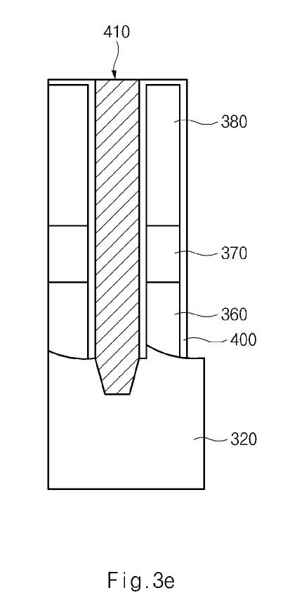

FIGS. 3a to 3e are cross-sectional views illustrating a method for manufacturing a semiconductor device according to an embodiment of the present invention.

Referring to FIG. 3a, a device isolating film 320 that defines an active region 310 is formed in a semiconductor substrate. The device isolating film 320 is formed to be higher than the active region 310 with a difference in height ranging from 300 to 600 Å. A hard mask layer 330 is formed over the resulting structure. The hard mask layer 330 includes Tetra Ethyl Ortho Silicate (TEOS), Thermal Oxide or High Density Plasma (HDP).

Referring to FIG. 3b, after a photoresist film is formed over the hard mask layer 330, a photoresist pattern (not shown) is formed by an exposing and developing process using a recess mask. The hard mask layer 330 is etched using the photoresist pattern as a mask. The active region 310 and the device isolating film 320 are etched using the hard mask layer 330 as a mask to form recesses 340. After each recess 340 is formed, the residual hard mask layer 330 is formed to have a thickness ranging from 150 to 250 Å.

Referring to FIG. 3c, each recess 340 of the device isolating film 320 and the active region 310 is planarized by a wet etching process to remove the residual hard mask layer 330. A wet target of the wet etching process is etched ranging from 200 to 400% to planarize the device isolating film 320 more than the wet target of a conventional method. An isotropic etching process is performed to etch the device isolating film 320 evenly using a wet etching process.

Referring to FIG. 3d, a gate oxide film 350, a polysilicon layer 360, a conductive layer 370 and a hard mask nitride film 380 are formed over the resulting structure including the recess 340. After a photoresist film is formed over the hard mask nitride film 380, a photoresist pattern (not shown) is formed by an exposing and developing process using a recess gate mask. The hard mask nitride film 380, the conductive layer 370, the polysilicon layer 360 and the gate oxide film 350 are etched using the photoresist pattern as a mask to form a recess gate 390.

FIG. 3e shows a magnified view of a region ‘B’ of FIG. 3d.

Referring to FIG. 3e, after the device isolating film 320 is etched to form the recess gate 390 of FIG. 3d, the top portion of the device isolating film 320 between adjacent recess gates 390 is formed to be planar, thereby preventing a failure of a self-aligned contact (SAC) between the gate polysilicon layer 360 and a polysilicon layer (not shown) for forming a contact plug 410 in a subsequent process. A nitride film 400 is formed over the resulting structure including the recess gate 390 of FIG. 3d. The nitride film 400 is etched so that a gate spacer is formed on sidewalls of the recess gate 390. An insulating film (not shown) is formed over the resulting structure including the recess gate 390.

The insulating film is etched to form a landing plug contact hole. A conductive material which includes polysilicon is filled in the landing contact hole, thereby forming the contact plug 410.

The above embodiments of the disclosure are illustrative and not limitative. Various alternatives and equivalents are possible. The invention is not limited by the type of deposition, etching, polishing, and patterning steps described herein. Nor is the invention limited to any specific type of semiconductor device. For example, the disclosure may be implemented in a dynamic random access memory (DRAM) device or a nonvolatile memory device. Other additions, subtractions, or modifications are obvious in view of the present disclosure and are intended to fall within the scope of the appended claims.

What is claimed is:

1. A method for manufacturing a semiconductor device, the method comprising:
forming a device isolating film that defines an active region over a semiconductor substrate;
forming a hard mask layer over the device isolating film and the active region;
etching the hard mask layer and the device isolating film to form a recess;
removing the hard mask layer and etching the device isolating film to planarize the recess by a wet etching process; and
forming a recess gate over the recess.

2. The method according to claim 1, wherein the device isolating film is higher than the active region.

3. The method according to claim 1, wherein the device isolating film has a step height difference with the active region ranging from 300 to 600 Å.

4. The method according to claim 1, wherein the hard mask layer is removed and the device isolating film is etched by an isotropic etching process.

5. The method according to claim 1, wherein the hard mask layer comprises one selected from Tetra Ethyl Ortho Silicate (TEOS), Thermal Oxide and High Density Plasma (HDP).

6. The method according to claim 1, wherein after the recess is formed, the hard mask layer has a thickness ranging from 150 to 250 Å.

7. The method according to claim 1, wherein forming the recess gate comprises:
forming a gate oxide film, a polysilicon layer, a conductive layer and a hard mask nitride film over the device isolating film including the recess; and
etching the hard mask nitride film, the conductive layer, the polysilicon layer and the gate oxide film.

8. The method according to claim 1, further comprising forming a spacer on sidewalls of the recess gate.

9. The method according to claim 8, wherein the spacer comprises a nitride film.

10. The method according to claim 1, further comprising:
forming an insulating film over the recess gate and the device isolating film;
etching the insulating film to form a landing plug contact hole; and
filling a conductive material in the landing plug contact hole to form a contact plug.

11. A method for manufacturing a semiconductor device, the method comprising:
forming a device isolating film that defines an active region over a semiconductor substrate;
forming a hard mask layer over the device isolating film and the active region;
etching the hard mask layer and the device isolating film to form a plurality of recesses;
etching the hard mask layer and the device isolating film to remove the hard mask layer and to planarize the device isolating film;
forming a recess gate over each of the plurality of recesses;
etching the device isolating film between each pair of adjacent recess gates, wherein the device isolating film between each pair of adjacent recess gates is etched to have a planar surface; and
forming a contact plug over the device isolating film between each pair of adjacent recess gates.

12. The method according to claim 11, wherein the device isolating film is higher than the active region.

13. The method according to claim 11, wherein the device isolating film has a step height difference with the active region ranging from 300 to 600 Å.

14. The method according to claim 11, wherein the hard mask layer and the device isolating film are etched by an isotropic etching process.

15. The method according to claim 11, wherein the hard mask layer includes one selected from Tetra Ethyl Ortho Silicate (TEOS), Thermal Oxide and High Density Plasma (HDP).

16. The method according to claim 11, wherein after the recesses are formed, the hard mask layer has a thickness ranging from 150 to 250 Å.

17. The method according to claim 11, wherein forming the recess gate comprises:
forming a gate oxide film, a polysilicon layer, a conductive layer and a hard mask nitride film over the device isolating film; and
etching the hard mask nitride film, the conductive layer, the polysilicon layer and the gate oxide film.

18. The method according to claim 11, further comprising forming a spacer on sidewalls of each recess gate.

19. The method according to claim 18, wherein the spacer comprises a nitride film.

20. The method according to claim 11, wherein forming the contact plugs comprises:
forming an insulating film over each recess gate and the device isolating film;
etching the insulating film to form a plurality of landing plug contact holes between each pair of adjacent recess gates; and
filling a conductive material in the landing plug contact holes.
